(19) United States
(12) Patent Application Publication
(10) Pub. No.: US 2017/0271404 A1
(43) Pub. Date: Sep. 21, 2017

(54) RESISTIVE CHANGE ELEMENT, NON-VOLATILE STORAGE DEVICE, AND PROGRAMMABLE LOGIC DEVICE

(71) Applicant: KABUSHIKI KAISHA TOSHIBA, Minato-ku (JP)

(72) Inventors: Yinghao HO, Kawasaki (JP); Koichiro Zaitsu, Kawasaki (JP); Shinichi Yasuda, Setagaya (JP)

(73) Assignee: KABUSHIKI KAISHA TOSHIBA, Minato-ku (JP)

(21) Appl. No.: 15/266,668

(22) Filed: Sep. 15, 2016

(30) Foreign Application Priority Data
Mar. 16, 2016 (JP) 2016-052709

(51) Int. Cl. H01L 27/24; G11C 13/00; H01L 45/00

(52) U.S. Cl. CPC H01L 27/2409; H01L 45/1253; H01L 45/146; G11C 13/0038

(57) ABSTRACT

A programmable logic device according to an embodiment includes: a plurality of first and second wiring lines; a plurality of resistive change elements each including a first electrode containing Ni and connected to corresponding one of the first wiring lines, a second electrode containing TiN and connected to corresponding one of the second wiring lines, a resistive change layer containing a hafnium oxide and arranged between the first electrode and the second electrode, and an insulation layer arranged between the resistive change layer and the second electrode, the insulation layer including at least one of an aluminum oxide, an iron oxide, a titanium oxide, a copper oxide, a nickel oxide, a tantalum oxide, a tungsten oxide, a chromium oxide, a rhenium oxide, and a hafnium oxynitride.

### CROSS REFERENCE TO RELATED APPLICATIONS

This application is based upon and claims the benefit of priority from prior Japanese Patent Application No. 2016-052709 filed on Mar. 16, 2016 in Japan, the entire contents of which are incorporated herein by reference.

### FIELD

Embodiments described herein relate generally to a resistive change element, a non-volatile storage device, and a programmable logic device.

### BACKGROUND

A programmable logic device is a semiconductor integrated circuit in which rewriting of the circuit after production of a chip is possible. The programmable logic device includes a plurality of wiring lines and makes two wiring lines selected from these wiring lines into an electrically connected state or non-connected state. A switching circuit is used to perform control in such a manner that the two selected wiring lines become the connected state or the non-connected state. In the switching circuit, a transistor and a memory are used. This memory can be electrically programmed and on/off of the transistor is switched based on programmed information. Also, what uses a two-terminal resistive change element as a memory and realizes the above switching circuit only with this memory is also known. This resistive change element includes two electrodes and a resistive change layer provided between these two electrodes. By applying predetermined voltage between the two electrodes, it is possible to change a resistive state of the resistive change layer and to switch electrical resistance between the two electrodes into a low resistive state or a high resistive state.

As described later, in a case where a resistive change element having a cross point structure is used as a switching circuit in a programmable logic device, it is necessary that the element has a low forming voltage and high off-resistance.

However, a resistive change element having a low forming voltage and high off-resistance is not known yet.

### BRIEF DESCRIPTION OF THE DRAWINGS

FIG. 1 is a diagram showing a switching circuit of a programmable logic device.

FIG. 2 is a sectional diagram showing a general resistive change element.

FIG. 3 is a diagram for explaining a forming operation of a resistive change element in the circuit shown in FIG. 1.

FIG. 4 is a sectional diagram showing a resistive change element according to a first embodiment.

FIG. 5 is a diagram showing forming voltages of resistive change elements of the first embodiment and a comparison example.

FIG. 6 is a diagram showing an energy band of the resistive change element of the first embodiment.

FIG. 7A and FIG. 7B are diagrams showing an energy band in a case where an insulation layer having a characteristic different from that of an insulation layer of the resistive change element of the first embodiment is used.

FIG. 8 is a diagram showing a measurement result of off-resistance and on-resistance of the resistive change element of the first embodiment.

FIG. 9A and FIG. 9B are diagrams showing current-voltage characteristics respectively in a set operation and a reset operation of the resistive change element of the first embodiment.

FIG. 10 is a diagram showing a switching circuit of a programmable logic device according to a second embodiment.

FIG. 11 is a diagram for explaining an example of a set operation in the programmable logic device according to the second embodiment.

FIG. 12 is a diagram for explaining a different example of a set operation in the programmable logic device according to the second embodiment.

FIG. 13 is a block diagram showing a non-volatile storage device according to a third embodiment.

FIG. 14 is a diagram showing a detailed example of a memory cell array of the non-volatile storage device of the third embodiment.

### DETAILED DESCRIPTION

A programmable logic device according to an embodiment includes: a plurality of first wiring lines; a plurality of second wiring lines intersecting with the first wiring lines; a plurality of resistive change elements disposed in cross regions of the plurality of first wiring lines and the plurality of second wiring lines, each of the resistive change elements including a first electrode containing Ni and connected to corresponding one of the first wiring lines, a second electrode containing TiN and connected to corresponding one of the second wiring lines, a resistive change layer containing a hafnium oxide and arranged between the first electrode and the second electrode, and an insulation layer arranged between the resistive change layer and the second electrode, the insulation layer including at least one of an aluminum oxide, an iron oxide, a titanium oxide, a copper oxide, a nickel oxide, a tantalum oxide, a tungsten oxide, a chromium oxide, a rhenium oxide, and a hafnium oxynitride, and in each of the resistive change elements, a resistive state between the first electrode and the second electrode being changeable from one of a first resistive state and a second resistive state having a resistance value larger than that of the first resistive state to the other; a first driver connected to the plurality of first wiring lines; and a second driver connected to the plurality of second wiring lines.

Before a description of embodiments of the present invention, how the present invention is invented will be described.

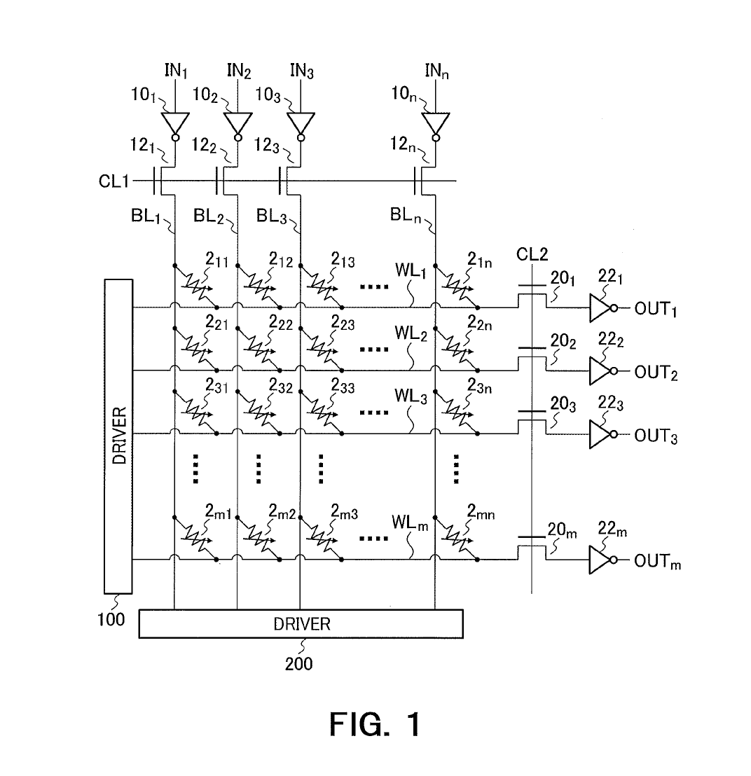

A programmable logic device includes a switching circuit. In this switching circuit, for example, a resistive change element is used as a memory element. A switching circuit in which a resistive change element is used as a memory element is shown in FIG. 1. This switching circuit includes a bit line group including a plurality of bit lines BL₁, BL₂, . . . , and BLₙ (n≧2), a word line group including a plurality of word lines WL₁, WL₂, . . . , and WLₘ (m≧2) intersecting with these bit lines, and a memory element 2ᵢⱼ provided in a cross region of each word line WLᵢ (i=1, . . . , m) and each bit line BLⱼ (j=1, . . . , n) (hereinafter, this structure is referred to as cross point structure). To each word line WLᵢ (i=1, . . . , m), one end of each of memory elements 2ᵢ₁ to 2ᵢₙ is connected. To each bit line BLⱼ (j=1, . . . , n), the other end of each of the memory elements 2₁ⱼ to 2ₘⱼ is connected. A driver 100 is connected to the word line group and a driver 200 is connected to the bit line group. A specific word line is selected by the driver 100. It is possible to apply voltage to the selected word line. A specific bit line is selected by the driver 200. It is possible to apply voltage to the selected bit line. That is, it is possible to program a selected memory cell.

In the switching circuit shown in FIG. 1, a memory element is a non-volatile resistive change element. The resistive change element includes two terminals (electrode) and can change resistance between the terminals into a low resistive state (LRS) or a high resistive state (HRS). In order to realize these state changes, a predetermined program voltage is applied between the terminals of the resistive change element. Here, changing a memory element from the HRS to the LRS is referred to as setting and changing the memory element from the LRS to the HRS is referred to as resetting.

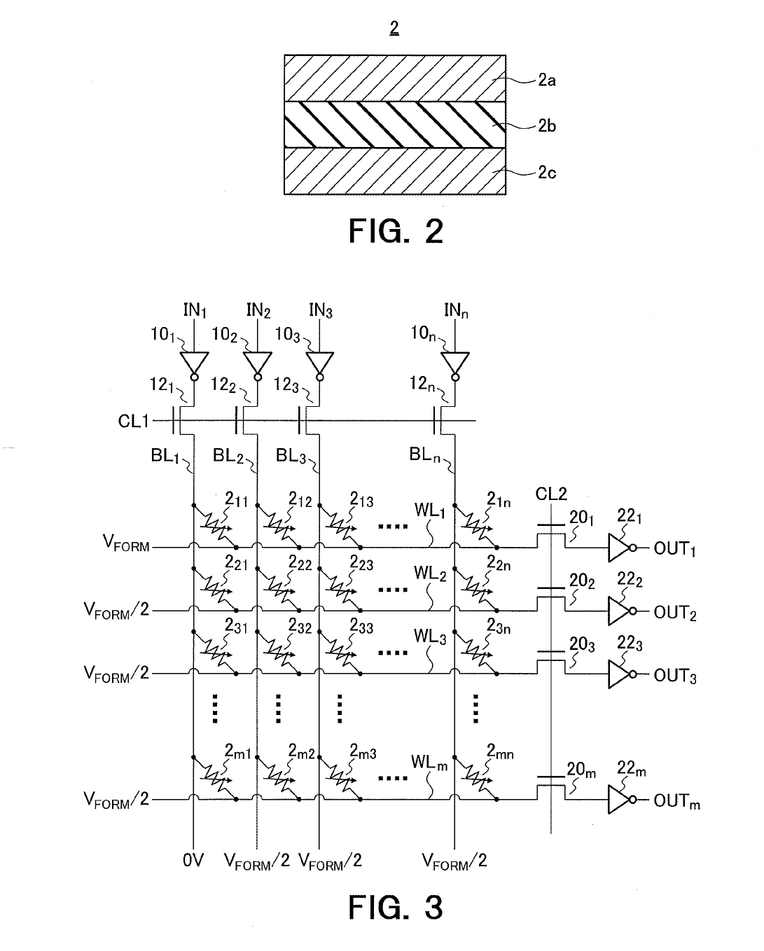

An example of a well-known resistive change element is shown in FIG. 2. A resistive change element 2 includes an upper electrode 2a, a lower electrode 2c, and a resistive change layer 2b provided between the upper electrode 2a and the lower electrode 2c.

As the resistive change element 2, there are a unipolar-type memory element and a bipolar-type memory element. In the unipolar-type resistive change element, a polarity of a set voltage and that of the reset voltage are identical.

For example, when voltage higher than voltage applied to an electrode 2a is applied to an electrode 2c in a case of setting a resistive change element 2, the voltage higher than the voltage applied to the electrode 2a is also applied to the electrode 2c in a case of resetting.

On the other hand, in the bipolar-type resistive change element, a polarity of a set voltage and that of a reset voltage are opposite. For example, when voltage higher than voltage applied to an electrode 2a is applied to an electrode 2c in a case of setting a resistive change element, voltage lower than the voltage applied to the electrode 2a is applied to the electrode 2c in a case of resetting.

It is determined whether a resistive change element is a unipolar-type or a bipolar-type according to a material included in an electrode or a resistive change layer or a voltage condition in forming, that is, a voltage condition or the like in operation of a memory function by application of predetermined voltage between electrodes of the resistive change element after production. Similarly, a polarity of a set voltage or reset voltage is determined according to a material included in an electrode or a resistive change layer, a voltage condition in forming, or the like.

Once a type of a resistive change element and polarities of a set voltage and a reset voltage are determined, these are not changed thereafter. Thus, in order to perform setting and resetting of the resistive change element 2 correctly, it is necessary that the electrode 2a and the electrode 2c are clearly distinguished from each other. In the present specification, one of the electrode 2a and the electrode 2c to which one high voltage is applied in resetting of the resistive change element 2 is referred to as an anode, and the other is referred to as a cathode. When a resistive change element 2 is the bipolar-type, higher voltage is applied to a cathode than to an anode, whereby setting is performed. On the other hand, when a resistive change element is the unipolar-type, higher voltage is applied to an anode than to a cathode, whereby setting is performed.

The switching circuit in the cross point structure which circuit is shown in FIG. 1 is used in switching of a wiring line in a programmable logic device. The switching circuit can switch connection and non-connection of a plurality of wiring lines when necessary. For example, when a resistive change element provided at an intersection point of two wiring lines is in the HRS, it can be considered that these wiring lines are not connected to each other. On the other hand, when the resistive change element is in the LRS, it can be considered that these wiring lines are connected to each other.

In the switching circuit shown in FIG. 1, a case where a signal is input into a bit line BLⱼ (j=1, . . . , n) through an input line INⱼ, an inverter 10ⱼ, and a transistor 12ⱼ and a signal is output from an output line OUTᵢ through a resistive change element 2ᵢⱼ in the LRS, a word line WLᵢ (i=1, . . . , m), a transistor 20ᵢ, and an inverter 22ᵢ is considered.

The bit line BLⱼ (j=1, . . . , n) is connected to an output of the inverter 10ⱼ through the transistor 12ⱼ a gate of which is connected to a wiring line CL1. This transistor 12ⱼ (j=1, . . . , n) is to block voltage, which is to program the resistive change element 12ᵢⱼ (i=1, . . . , m), from the inverter 10ⱼ. The transistor 12ⱼ (j=1, . . . , n) is turned off in a case of programming (setting or resetting) the resistive change element 2ᵢⱼ. However, in a case where a program voltage of the resistive change element is low, there may not be the transistor 12ⱼ (j=1, . . . , n). Also, in FIG. 1, an N-type transistor is used as the transistor 12ⱼ (j=1, . . . , n). However, a P-type transistor may be used.

On the other hand, the word line WLᵢ (i=1, . . . , m) is connected to an input of the inverter 22ᵢ through the transistor 20ᵢ a gate of which is connected to a wiring line CL2. This transistor 20ᵢ (i=1, . . . , m) is also to block voltage, which is to program the resistive change element 2ᵢⱼ, from the inverter 22ᵢ. The transistor 20ᵢ (i=1, . . . , m) is turned off in a case of programming (setting or resetting) the resistive change element.

However, in a case where a program voltage of the resistive change element is low, there may not be the transistor 20ᵢ (i=1, . . . , m). Also, in FIG. 1, an N-type transistor is used as the transistor 20ᵢ (i=1, . . . , m). However, a P-type transistor may be used.

Moreover, the transistors 12ⱼ (j=1, . . . , n) and 20ᵢ (i=1, . . . , m) are respectively provided on an input side and an output side of a signal in FIG. 1. However, in a case where the resistive change element 2ᵢⱼ is the unipolar-type resistive change element, the transistor 12ⱼ (j=1, . . . , n) or the transistor 20ᵢ (i=1, . . . , m) may be provided only on one side.

For example, in FIG. 1, in a case where a resistive change element 2₁₁ is in the LRS and resistive change elements 2₁₂, 2₁₃, . . . , 2₁ₙ are in the HRS, it can be considered that a bit line BL₁ and a word line WL₁ are connected and that bit lines BL₂, BL₃, . . . , and BLₙ and the word line WL₁ are not connected. That is, a signal input from an input line IN₁ is output from an output line OUT₁.

Also, for example, in a case where resistive change elements 2₁₁ and 2₂₁ are in the LRS and resistive change elements 2₁₂, 2₁₃, . . . , and 2₁ₙ, and 2₂₂, 2₂₃, . . . , and 2₂ₙ are in the HRS in FIG. 1, it can be considered that the bit line BL₁ is connected to word lines WL₁ and WL₂ and that the bit lines BL₂, BL₃, . . . , and BLₙ are not connected to either of the word lines WL₁ and WL₂. That is, a signal input from the input line IN₁ is output from both of output lines OUT₁ and OUT₂.

As described above, it is considered as an example of a pattern of switching of a wiring line that a signal input into one input line is output from a plurality of output lines. However, it is not considered that signals input into a plurality of input lines are output from one output line. In other words, there is a case where a plurality of resistive change elements among resistive change elements connected to the same input line is in the LRS. However, there is not a case where a plurality of resistive change elements among resistive change elements connected to the same output line is in the LRS.

Next, a case where the resistive change element 2₁₁ is formed in the switching circuit shown in FIG. 1 will be described with reference to FIG. 3. Here, it is assumed that a forming voltage necessary for forming is V_{FORM}.

0 V is applied to the bit line BL₁ and a forming voltage V_{FORM} is applied to the word line WL₁. Accordingly, since the forming voltage V_{FORM} is applied between terminals of the resistive change element 2₁₁, forming is generated in the resistive change element 2₁₁. On the other hand, voltage, which is between 0 V and the forming voltage V_{FORM}, such as V_{FORM}/2 is applied to the other bit lines BL₂ to BLₙ and the other word lines WL₂ to WLₘ. This is to prevent a program disturbance (setting disturbance or resetting disturbance) of a not-selected resistive change element.

However, in a case where V_{FORM}/2 is higher than a set voltage Vₛₑₜ necessary for setting a resistive change element in the forming, a voltage difference Δ V applied to a not-selected resistive change element such as a resistive change element 2ᵢ₁ (i=2, . . . , m) becomes the voltage V_{FORM}/2 and erroneous-setting is generated. Thus, there is a problem that an arbitrary rewriting operation cannot be performed.

Also, in a case where the forming voltage V_{FORM} is high, there is possibility that a gate insulation film of the transistor 20₁ gets broken. There is a problem that a high-voltage transistor having a large area is used as the transistor 20ᵢ (i=1, . . . , m) in order to prevent this and occupies a large area in a chip.

Also, when off-resistance of a resistive change element is low, current easily flows. Thus, there is a problem that power consumption is increased.

Thus, the present inventors have made efforts on a research and have found a resistive change element having a low forming voltage and high off-resistance. This resistive change element will be described as a first embodiment.

### First Embodiment

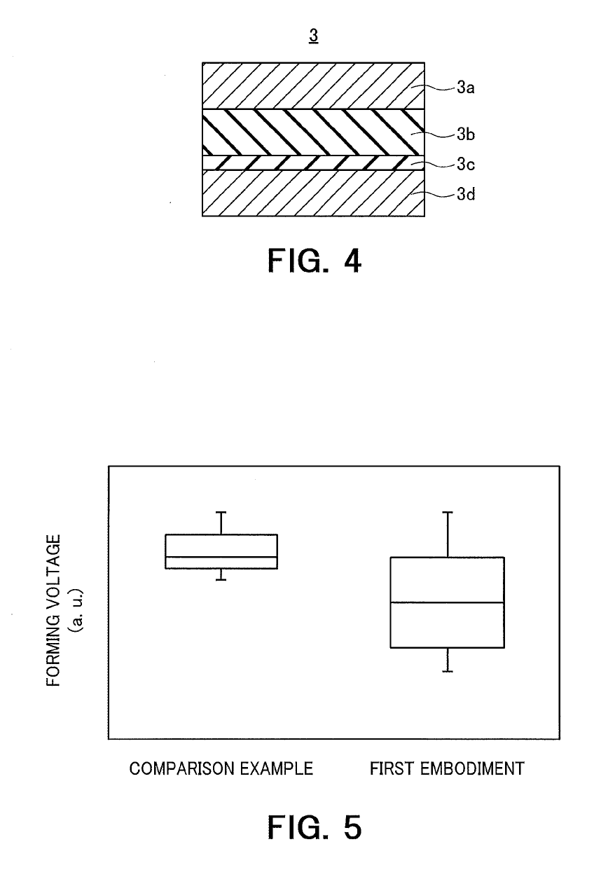

A resistive change element according to the first embodiment is shown in FIG. 4. A resistive change element 3 of the first embodiment includes an Ni electrode 3a, a TiN electrode 3d, a resistive change layer 3b arranged between the Ni electrode 3a and the TiN electrode 3d, and an insulation layer 3c arranged between the resistive change layer 3b and the TiN electrode 3d.

As the resistive change layer 3b, a hafnium oxide, that is, HfOₓ (0<x<2) is used. As the insulation layer 3c, at least one of an aluminum oxide (such as AIO₂), an iron oxide (such as Fe₂O₃, Fe₃O₄, Fe₄O₂, or Fe₄O₆), a titanium oxide (such as TiO₂), a copper oxide (such as Cu₂O₂, Cu₂O₃, or Cu₂O₄), a nickel oxide (such as NiO₂), a tantalum oxide (such as Ta₂O₅), a tungsten oxide (WO₃), a chromium oxide (CrO₃), a rhenium oxide (such as ReO₃), and a hafnium oxynitride is used. In the insulation layer 3c, an oxygen deficiency is preferably included for forming of a filament to conduct an electron.

The resistive change element 3 of this first embodiment and a resistive change element of a comparison example in which element an insulation layer 3c is not arranged in the resistive change element of the first embodiment are manufactured and forming voltages of these are investigated. A result of that is shown in FIG. 5. As it is understood from FIG. 5, an average value of the forming voltage of the resistive change element of the first embodiment is low compared to an average value of the forming voltage of the resistive change element of the comparison example. Note that a center line in each square indicates a median value in FIG. 5. (Forming voltage)

Next, a reason why the forming voltage of the resistive change element 3 of the first embodiment configured in such a manner becomes low will be described.

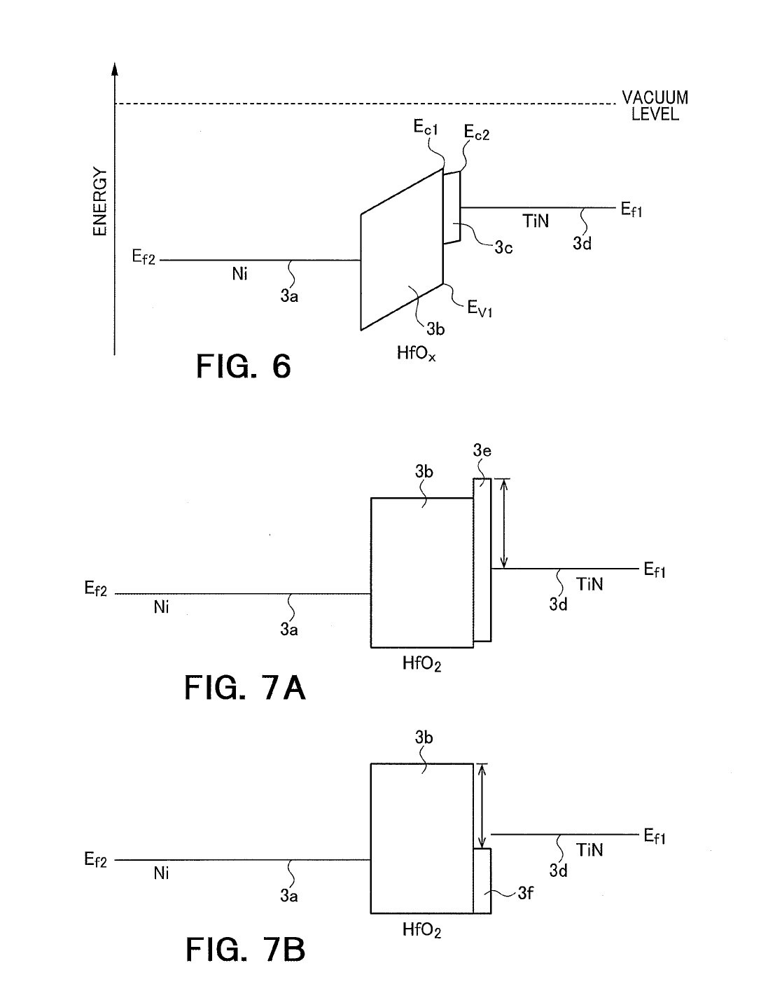

An energy band diagram in a case where voltage of 3 V is applied to the Ni electrode 3a and voltage of 0 V is applied to the TiN electrode 3d in the resistive change element 3 of the first embodiment is shown in FIG. 6. As it can be understood from FIG. 6, in the resistive change element 3 of the first embodiment, a bottom of a conduction band Ec2 of the insulation layer 3c is lower than a bottom of a conduction band Ec1 of the resistive change layer 3b and is higher than a Fermi level Ef1 of the TiN electrode 3d. Note that in the resistive change layer shown in FIG. 6, HfOₓ is used as the resistive change layer 3b and a titanium oxide is used as the insulation layer 3c.

Since the insulation layer 3c having such a characteristic is arranged between the resistive change layer 3b and the TiN electrode 3d, when a forming voltage is applied, an electron from the TiN electrode 3d exceeds an energy barrier between the bottom of a conduction band Ec2 of the insulation layer 3c and the Fermi level Ef1 of the TiN electrode 3d and an energy barrier between the bottom of a conduction band Ec1 of HfOₓ and the bottom of a conduction band Ec2 of the insulation layer 3c, and is conducted to the Ni electrode 3a through the insulation layer 3c and the resistive change layer 3b. Note that in FIG. 6, Ev1 indicates a peak of a valence band of the resistive change layer 3b and Ef2 indicates a Fermi level of the Ni electrode 3a.

On the other hand, when a forming voltage is applied in the resistive change element of the comparison example, an electron from a TiN electrode 3d exceeds an energy barrier between a bottom of a conduction band Ec1 of HfOₓ and a Fermi level Ef1 of the TiN electrode 3d and is conducted to an Ni electrode 3a through a resistive change layer 3b.

An energy difference between the bottom of a conduction band Ec2 of the insulation layer 3c and the Fermi level Ef1 of the TiN electrode 3d is smaller than an energy difference between the bottom of a conduction band Ec1 of HfOₓ and the Fermi level Ef1 of the TiN electrode 3d. Thus, it is considered that an electron easily exceeds an energy barrier and that a forming voltage becomes low in the resistive change element 3 of the present embodiment compared to the resistive change element of the comparison example.

Accordingly, it is preferable that an electron affinity, that is, an energy difference between a vacuum level and a bottom of a conduction band is higher than an electron affinity (=2.65 eV) of HfOₓ and is lower than a work function of TiN, that is, an energy difference between a vacuum level and a Fermi level of TiN in the insulation layer 3c used in the resistive change layer of the present embodiment. This is because it becomes difficult for an electron to exceed an energy barrier compared to the present embodiment in a case where an electron affinity of an insulation layer 3e is equal to or lower than the electron affinity (=2.65 eV) of HfOₓ as shown in FIG. 7A. Also, this is because it becomes difficult for an electron to exceed an energy barrier compared to the present embodiment in a case where an electron affinity of an insulation layer 3f is equal to or higher than a work function (=4.45 eV) of TiN as shown in FIG. 7B. Note that FIG. 7A and FIG. 7B are diagrams showing energy bands in a case where no voltage is applied between the Ni electrode 3a and the TiN electrode 3d.

As it is understood from the above description, the resistive change element of the present embodiment is preferably used as a unipolar-type resistive change element.

(Off-Resistance)

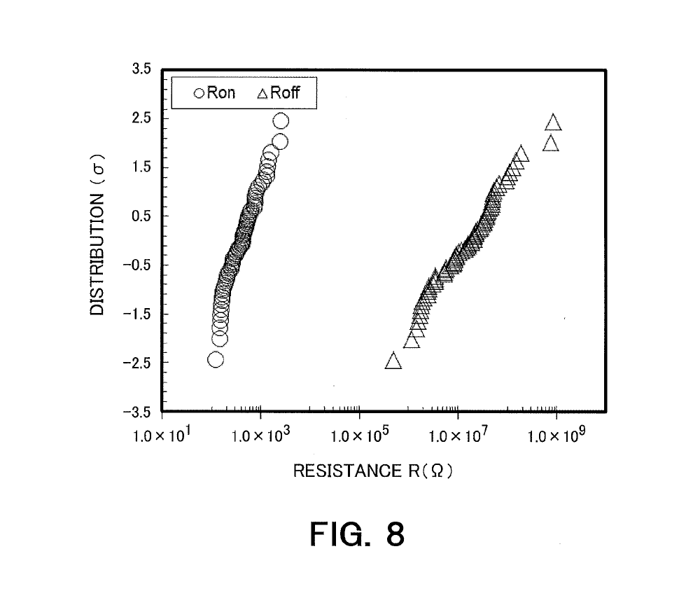

Next, the resistive change element of the first embodiment is manufactured, on-resistance Ron and off-resistance Roff are measured, and a result thereof is shown in FIG. 8. Note that HfOₓ is used as the resistive change layer 3b and a titanium oxide is used as the insulation layer 3c. As it is understood from FIG. 8, an average value of the off-resistance Roff is in order of 10⁷ while an average value of the on-resistance Ron is in order of 10². It is understood that the off-resistance Roff is higher for 100 kΩ. By acquiring such high off-resistance, it is possible to decrease power consumption in an operation of a programmable logic device of a second embodiment described later. Note that in the present embodiment, and the second embodiment and a third embodiment that are described later, it is preferable that off-resistance is equal to or higher than 100 kΩ.

Also, the resistive change element 3 of the first embodiment has few rectification characteristics. That is, when the resistive change element 3 is in the low resistive state, a ratio I1/I2 of current I1, which flows in a case where predetermined voltage is applied to the resistive change element 3 in such a manner that current flows from the TiN electrode 3d to the Ni electrode 3a, to current I2 that flows in a case where voltage, a polarity of which is inverted from that of the predetermined voltage, is applied to the resistive change element 3 in such a manner that current flows from the Ni electrode 3a to the TiN electrode 3d is equal to or higher than 1/10 and is equal to or lower than 10.

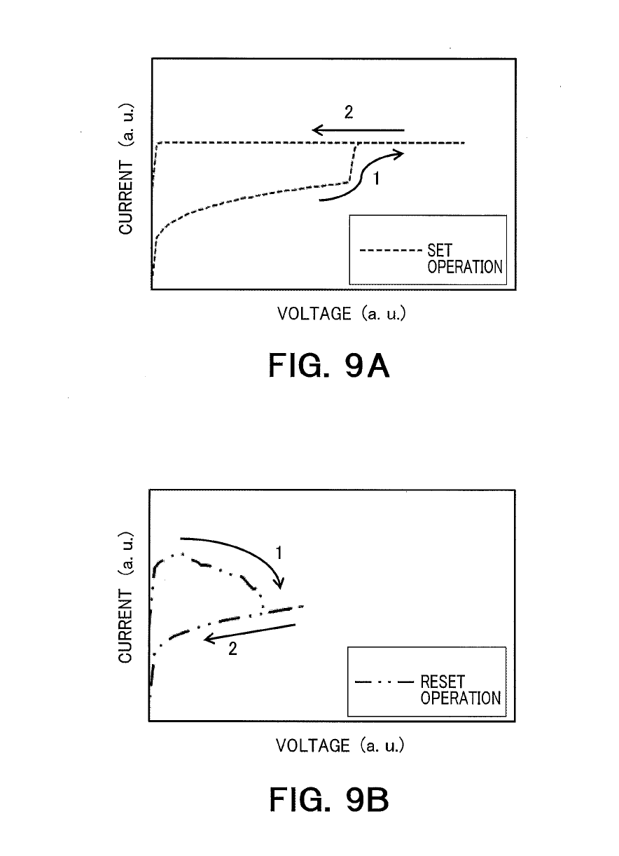

Next, current-voltage characteristics in a case where a set operation and a reset operation of the resistive change element 3 of the first embodiment are performed are respectively shown in FIG. 9A and FIG. 9B.

In the set operation, when voltage applied to the resistive change element 3 is increased, current flowing in the resistive change element 3 is suddenly increased at certain predetermined voltage. Even when the voltage is then decreased, the current flowing in the resistive change element 3 is kept high (FIG. 9A).

In the reset operation, when voltage applied to the resistive change element 3 is increased, current flowing in the resistive change element 3 is decreased after being slightly increased. Even when the voltage is then decreased, the current flowing in the resistive change element 3 is kept low (FIG. 9B).

As described above, according to the first embodiment, it is possible to provide a resistive change element having a low forming voltage and high off-resistance.

### Second Embodiment

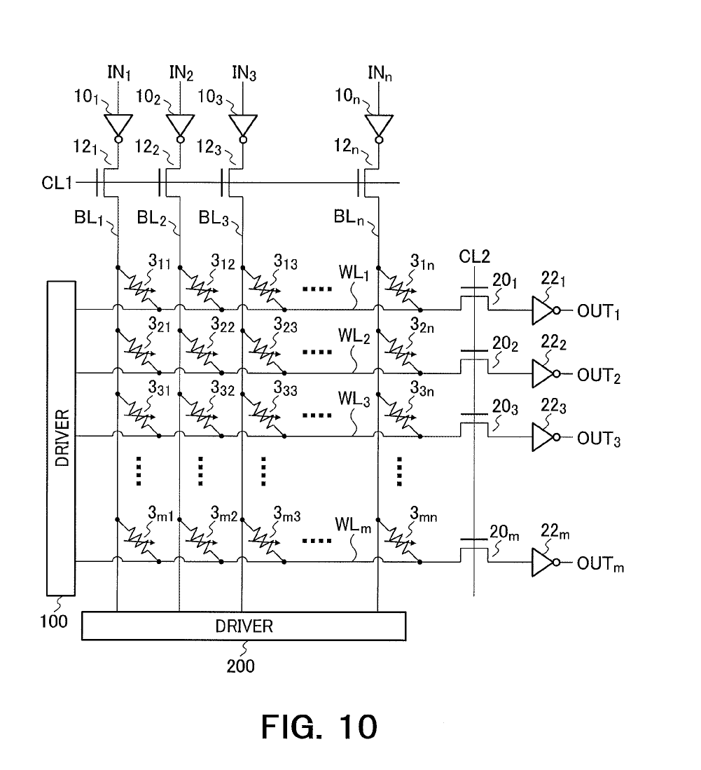

Next, a programmable logic device according to the second embodiment will be described with reference to FIG. 10. FIG. 10 is a diagram showing a switching circuit included in the programmable logic device of the second embodiment. This switching circuit has a configuration in which a resistive change element 2ᵢⱼ (i=1, . . . , m, j=1, . . . , n) is replaced with a resistive change element 3ᵢⱼ in the programmable logic device shown in FIG. 1. This resistive change element 3ᵢⱼ (i=1, . . . , m, j=1, . . . , n) is the resistive change element 3 of the first embodiment.

The switching circuit included in the programmable logic device of this second embodiment has a configuration in which a resistive change element 2ᵢⱼ (i=1, . . . , m, j=1, . . . , n) is replaced with the resistive change element 3 of the first embodiment in the switching circuit shown in FIG. 1. Thus, a description of a relationship in connection of configuration elements is omitted.

Next, a programming method in a case of changing (setting) a resistive change element 3₁₁ from an HRS to an LRS in the switching circuit shown in FIG. 10 is considered. Here, it is assumed that a program voltage necessary for setting is Vpgm.

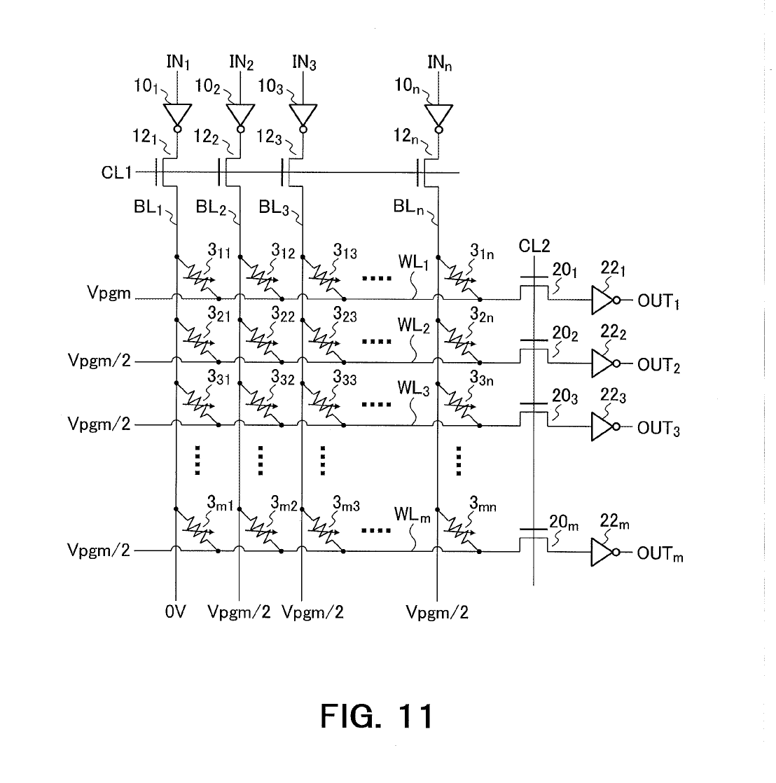

An example of the method of setting the resistive change element 3₁₁ is shown in FIG. 11. 0 V is applied to a bit line BL₁ and a program voltage Vpgm is applied to a word line WL₁. Accordingly, since the program voltage Vpgm is applied between terminals of the resistive change element 3₁₁, the resistive change element 3₁₁ is set. On the other hand, voltage, which is between 0 V and the program voltage Vpgm, such as Vpgm/2 is applied to the other bit lines BL₂ to BLₙ and the other word lines WL₂ to WLₘ. This is to prevent a program disturbance (setting disturbance or resetting disturbance) of a not-selected resistive change element. In a case shown in FIG. 11, it is preferable that an Ni electrode 3a of each resistive change element 3ᵢⱼ (i=1, . . . , m, j=1, . . . , n) is connected to a word line WLᵢ and a TiN electrode 3d thereof is connected to a bit line BLⱼ.

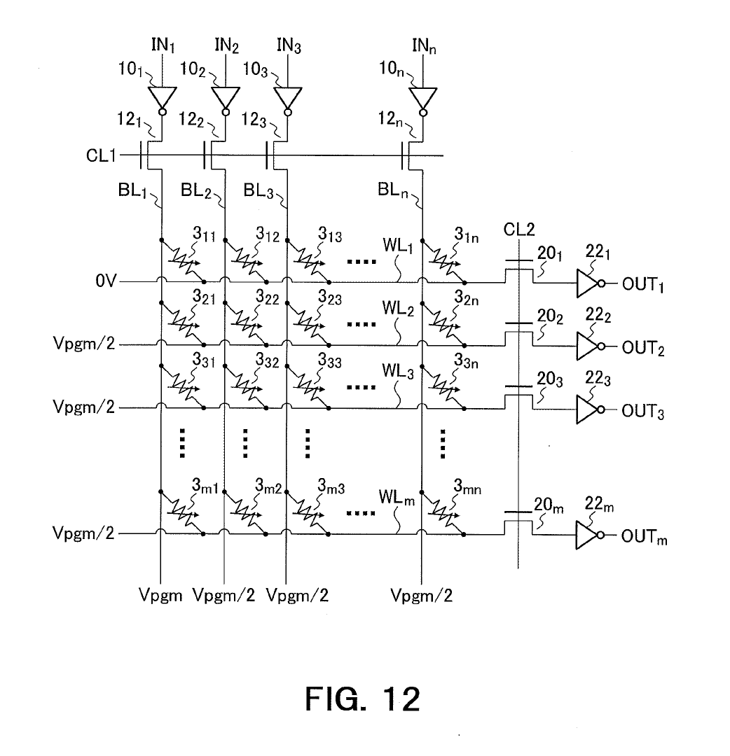

A different example of the method of setting the resistive change element 3₁₁ is shown in FIG. 12. A program voltage Vpgm is applied to the bit line BL₁ and 0 V is applied to the word line WL₁. Accordingly, since the program voltage Vpgm is applied between terminals of the resistive change element 3₁₁, the resistive change element 3₁₁ is set. On the other hand, voltage, which is between 0 V and the program voltage Vpgm, such as Vpgm/2 is applied to the other bit lines BL₂ to BLₙ and the other word lines WL₂ to WLₘ. In a case shown in FIG. 12, it is preferable that a TiN electrode 3d is connected to a word line WLᵢ and a Ni electrode 3a is connected to a bit line BLⱼ in each resistive change element 3ᵢⱼ (i=1, . . . , m, j=1, . . . , n).

Note that in a case of programming the resistive change element, voltage applied to a plurality of word lines is controlled by a driver 100 and voltage applied to a plurality of bit lines is controlled by a driver 200.

As described above, according to the second embodiment, since the resistive change element of the first embodiment is used as a resistive change element, it is possible to provide a programmable logic device that includes a resistive change element having a low forming voltage and high off-resistance.

### Third Embodiment

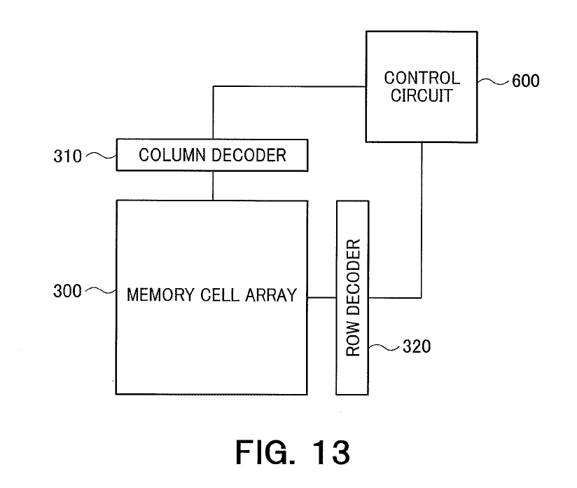

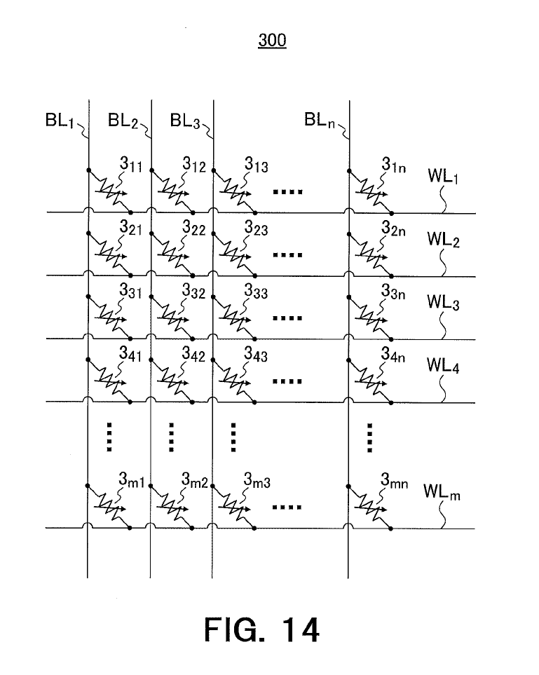

A non-volatile storage device according to the third embodiment is shown in FIG. 13. The non-volatile storage device of this third embodiment includes a memory cell array 300, a column decoder 310, a row decoder 320, and a control circuit 600. As shown in FIG. 14, the memory cell array 300 includes resistive change elements 3ᵢⱼ arranged in cross regions of a plurality of word lines WLᵢ (i=1, . . . , m) and a plurality of bit lines BLⱼ (j=1, . . . , n). Each resistive change element 3ᵢⱼ (i =1, . . . , m, j=1, . . . , n) is the resistive change element 3 of the first embodiment.

The column decoder 310 is connected to the bit lines BL₁ to BLₙ and selects a resistive change element 3ᵢⱼ (i=1, . . . , m) connected to each bit line BLⱼ (j=1, . . . , n).

The row decoder 320 is connected to the word lines WL₁ to WLₘ and selects a resistive change element 3ᵢⱼ (j=1, . . . , n) connected to each word line WLᵢ (i=1, . . . , m).

In a case of performing writing into the resistive change element, that is, in a case of setting the resistive change element, the writing is performed in a manner similar to that in the case described in the second embodiment.

For example, in a case of setting a resistive change element 3₁₁, 0 V is applied to the bit line BL₁ and a program voltage Vpgm is applied to the word line WL₁ as described in FIG. 11. Accordingly, since the program voltage Vpgm is applied between terminals of the resistive change element 3₁₁, the resistive change element 3₁₁ is set. On the other hand, voltage, which is between 0 V and the program voltage Vpgm, such as Vpgm/2 is applied to the other bit lines BL₂ to BLₙ and the other word lines WL₂ to WLₘ. This is to prevent a program disturbance (setting disturbance or resetting disturbance) of a not-selected resistive change element. In a case shown in FIG. 11, it is preferable that an Ni electrode 3a of each resistive change element 3ᵢⱼ (i=1, . . . , m, j=1, . . . , n) is connected to a word line WLᵢ and a TiN electrode 3d thereof is connected to a bit line BLⱼ.

Also, for example, in a case of setting the resistive change element 3₁₁, a program voltage Vpgm is applied to the bit line BL₁ and 0 V is applied to the word line WL₁ as described in FIG. 12. Accordingly, since the program voltage Vpgm is applied between terminals of the resistive change element 3₁₁, the resistive change element 3₁₁ is set. On the other hand, voltage, which is between 0 V and the program voltage Vpgm, such as Vpgm/2 is applied to the other bit lines BL₂ to BLₙ and the other word lines WL₂ to WLₘ. In a case shown in FIG. 12, it is preferable that a TiN electrode 3d is connected to a word line WLᵢ and a Ni electrode 3a is connected to a bit line BLⱼ in each resistive change element 3ᵢⱼ (i=1, . . . , m, j=1, . . . , n).

Note that in a case of programming the resistive change element, voltage applied to the plurality of word lines WL₁ to WLₘ is controlled by the control circuit 600 through the row decoder 320 and voltage applied to the plurality of bit lines BL₁ to BLₙ is controlled by the control circuit through the column decoder 310.

In the non-volatile storage device shown in FIG. 14, it is independent whether each resistive change element is in an LRS or an HRS. Also, it is arbitrarily set which resistive change element among a plurality of resistive change elements connected to the same bit line or the same word line is in the LRS or how many resistive change elements thereamong are in the LRS. Thus, there is a case where all of resistive change elements 3₁₁ to 3ₘₙ are in the LRS or a case where the all thereof are in the HRS.

As described above, according to the third embodiment, since the resistive change element of the first embodiment is used as a memory element, it is possible to provide a non-volatile storage device that includes a resistive change element having a low forming voltage and high off-resistance.

1. A programmable logic device comprising:
a first wiring;
a second wiring intersecting with the first wiring;
a resistive change element disposed in cross region of the first wiring and the second wiring, the resistive change element including a first electrode containing Ni and connected to corresponding one of the first wiring, a second electrode containing TiN and connected to the second wiring, a resistive change layer containing a hafnium oxide and arranged between the first electrode and the second electrode, and an insulation layer arranged between the resistive change layer and the second electrode, the insulation layer including at least one of an aluminum oxide, an iron oxide, a titanium oxide, a copper oxide, a nickel oxide, a tantalum oxide, a tungsten oxide, a chromium oxide, and a rhenium oxide, and in the resistive change element, a resistive state between the first electrode and the second electrode being changeable from one of a first resistive state and a second resistive state having a resistance value larger than that of the first resistive state to the other;
a first driver connected to the first wiring; and
a second driver connected to the second wiring.

2. The logic device according to claim 1, wherein when the resistive change element is in the first resistive state, a ratio of first current to second current is equal to or higher than 1/10 and equal to or lower than 10, the first current flowing in a case where predetermined voltage is applied to the resistive change element in such a manner that the first current flows from the second electrode to the first electrode, and the second current flowing in a case where voltage, which has an opposite polarity of the predetermined voltage, is applied to the resistive change element in such a manner that the second current flows from the first electrode to the second electrode.

3. The device according to claim 1, wherein the resistive change element is a unipolar-type.

4. The device according to claim 1, wherein the insulation layer includes a material with an electron affinity being in a range higher than 2.65 eV and lower than 4.45 eV.

5. A non-volatile storage device comprising:
a first wiring;
a second wiring intersecting with the first wiring;
a resistive change element disposed in cross region of the first wiring and the second wiring, the resistive change element including a first electrode containing Ni and connected to the first wiring, a second electrode containing TiN and connected to the second wiring, a resistive change layer containing a hafnium oxide and arranged between the first electrode and the second electrode, and an insulation layer arranged between the resistive change layer and the second electrode, the insulation layer including at least one of an aluminum oxide, an iron oxide, a titanium oxide, a copper oxide, a nickel oxide, a tantalum oxide, a tungsten oxide, a chromium oxide, and a rhenium oxide, and in the resistive element, a resistive state between the first electrode and the second electrode being changeable from one of a first resistive state and a second resistive state having a resistance value larger than that of the first resistive state to the other;
a first voltage application circuit connected to the first wiring; and
a second voltage application circuit connected to the second wiring.

6. The device according to claim 5, wherein the resistive change element is a unipolar-type.

7. The device according to claim 5, wherein the insulation layer includes a material with an electron affinity being in a range higher than 2.65 eV and lower than 4.45 eV.

8. A resistive change element comprising:
a first electrode including Ni;
a second electrode including TiN;
a resistive change layer including a hafnium oxide and arranged between the first electrode and the second electrode; and
an insulation layer arranged between the resistive change layer and the second electrode, the insulation layer including at least one of an aluminum oxide, an iron oxide, a titanium oxide, a copper oxide, a nickel oxide, a tantalum oxide, a tungsten oxide, a chromium oxide, and a rhenium oxide.

9. The resistive change element according to claim 8, wherein the insulation layer includes a material with an electron affinity being in a range higher than 2.65 eV and lower than 4.45 eV.
